(19) United States
(12) Patent Application Publication
(10) Pub. No.: US 2004/0094771 A1
(43) Pub. Date: May 20, 2004

(54) Device with at least two organic electronic components and method for producing the same

(76) Inventors: Adolf Bernds, Baiersdorf (DE); Wolfgang Clemens, Puschendorf (DE); Walter Fix, Nurnberg (DE); Markus Lorenz, Nurnberg (DE); Henning Rost, Erlangen (DE)

Correspondence Address: YOUNG & THOMPSON, 745 SOUTH 23RD STREET 2ND FLOOR, ARLINGTON, VA, 22202

(21) Appl. No.: 10/473,050

(22) PCT Filed: Mar. 15, 2002
(86) PCT No.: PCT/DE02/00937

(30) Foreign Application Priority Data
Mar. 26, 2001 (DE) 101 14 879.8

(51) Int. Cl. H01L 33/00

(52) U.S. Cl. 257/100

(57) ABSTRACT

The invention relates to a device with at least two organic electronic components that comprise at least one organic functional layer, as well as to a method for producing the same. Unlike conventional devices, the inventive device comprises at least two components from organic material and is therefore substantially less expensive and less complicated to produce than known devices that require a combination of organic with conventional electronic components. The inventive device completely eliminates, under certain circumstances, the need for conventional silicon semiconductor technology.

The invention relates to a device with at least two electronic components that comprise at least one organic functional layer, as well as to a method for producing the same.

A device, such as for example a display with at least one organic functional layer, is known, which is controlled by an external conventional electronics system (i.e. one operating using semiconductor materials containing silicon). A solar cell/photocell with at least one organic functional layer is also known, which however has the disadvantage that, like the displays, it has to be controlled by means of conventional electronics systems.

The disadvantage of the devices with at least two electronic components known to date is that they comprise components from conventional silicon semiconductor technology, which are significantly more expensive with regard to process costs and production than the organic electronic components.

The object of the present invention is therefore to provide a complex device, i.e. one comprising at least two electronic components, which can be produced simply and cheaply, so that it can be used economically as a disposable product.

The object of the invention is a device with at least two electronic organic components, with the two components each comprising at least one organic functional layer and having a direct or indirect functional connection.

The object of the invention is also a method for producing such a device with at least two electronic organic components, with the electronic organic components being such that they can be produced by printing, spraying, coating, embossing, imprinting, heating and/or irradiating a substrate.

At the time of production the substrate is either coated or uncoated. If it is coated, a functional layer can be produced by irradiation. Functional layers can be produced on the uncoated substrate by printing and/or embossing and applying a functional polymer etc. with a doctor blade.

A component with at least one organic functional layer is referred to as an electronic organic component, i.e. it comprises at least one essential electronic component, such as for example the semiconducting and/or conducting layer made of organic material.

The term “organic material” and/or “organic” here covers all types of organic, organometallic and/or inorganic plastics. These are all the types of material, with the exception of semiconductors, which are used for classic diodes (germanium, silicon) and typical metal conductors. A restriction in the dogmatic sense to organic material as material containing carbon is therefore not specified, rather the wide use of silicons for example is intended. Also the term should not imply any restriction with regard to molecule size, in particular polymer and/or oligomer materials, but the use of small molecules is also definitely possible.

“Direct functional” here refers to a connection between two modules, which exists without a further interim module and “indirect functional” a connection in which there are other interim

modules. For example in the case of a pocket calculator the display and energy storage unit have a direct connection, while the display and the keyboard have an indirect connection, for example via pressure sensors.

All types of component, which are parts of more complex devices such as pocket calculators, displays with operating elements or sensors (for pressure, temperature, light, etc.), are referred to as electronic components. Examples of such components are: Diodes, light and/or photodiodes, photocells, solar cells, transistors, organic field-effect transistors, displays (or LEDs, lamps), electronic control systems, keyboards, batteries, computers, integrated circuits (IC), screens, passive components such as resistors, capacitors and/or coils.

At least two organic electronic components are combined in a device, examples of such devices being:

Pocket calculators, displays with operating elements and/or sensors, such as pressure, temperature or light sensors. Also one or two electronic organic components can be integrated in a housing and/or on a substrate of a device and/or the integration of electronics systems in printed circuit boards can create a device with at least two electronic organic components.

The devices comprise at least two organic electronic components but can also comprise any number of other electronic components, which in turn can also be produced with conventional semiconductor technology. The at least two electronic components can supplement each other, such as for example a light-emitting and a light-detecting component in combination with an active matrix display or a pressure sensor with a light-emitting component, etc. There is no restriction here in the sense that a device and the associated

control system represent the at least two devices, rather a combination of two independent devices of the same organic semiconductor technology in particular is intended.

The invention is described below using four figures, which disclose examples of embodiments of the invention:

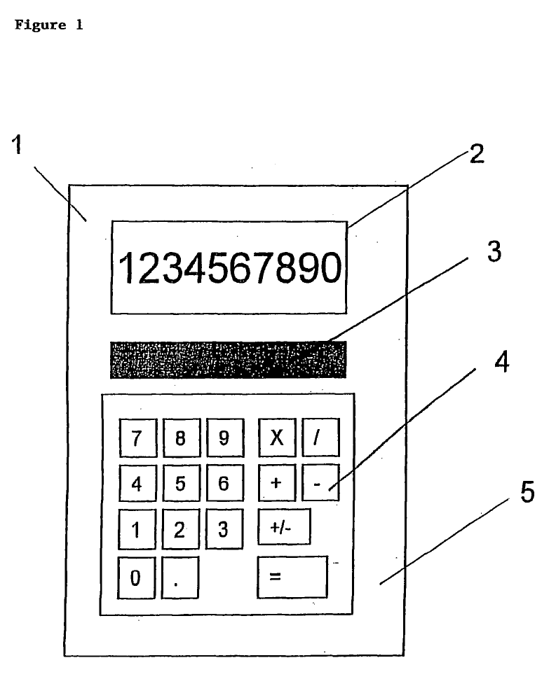

FIG. 1 shows a pocket calculator viewed from above,

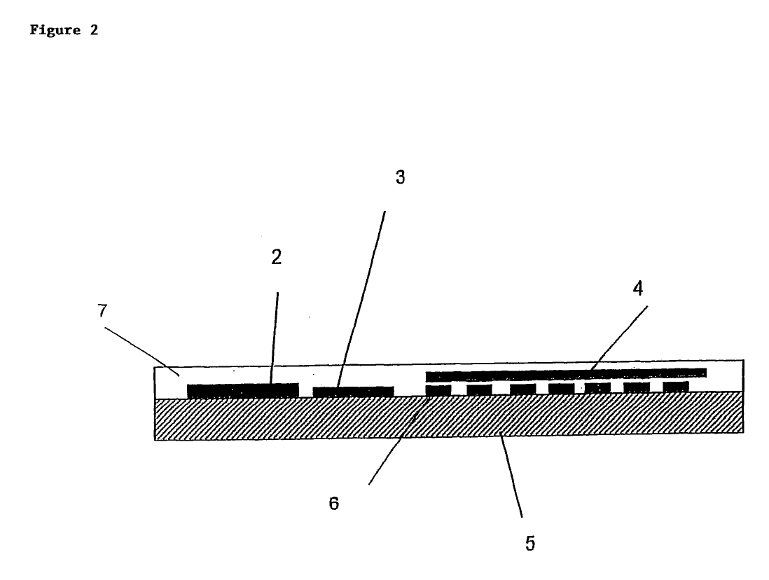

FIG. 2 shows a cross-section through a pocket calculator,

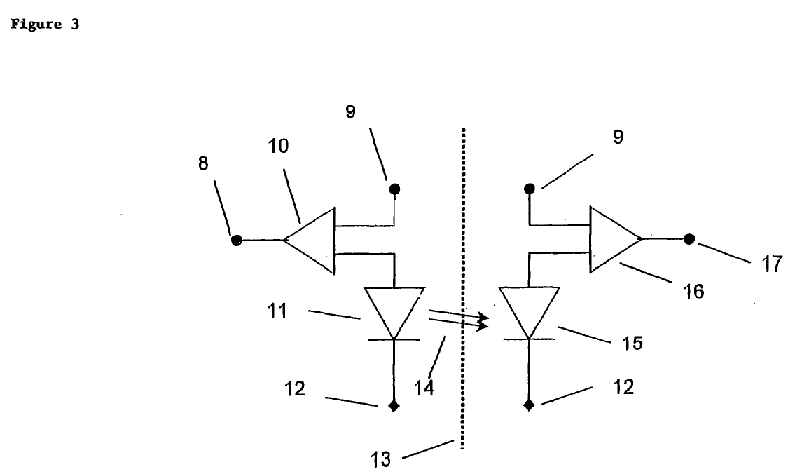

FIG. 3 shows a circuit for an optical coupler and

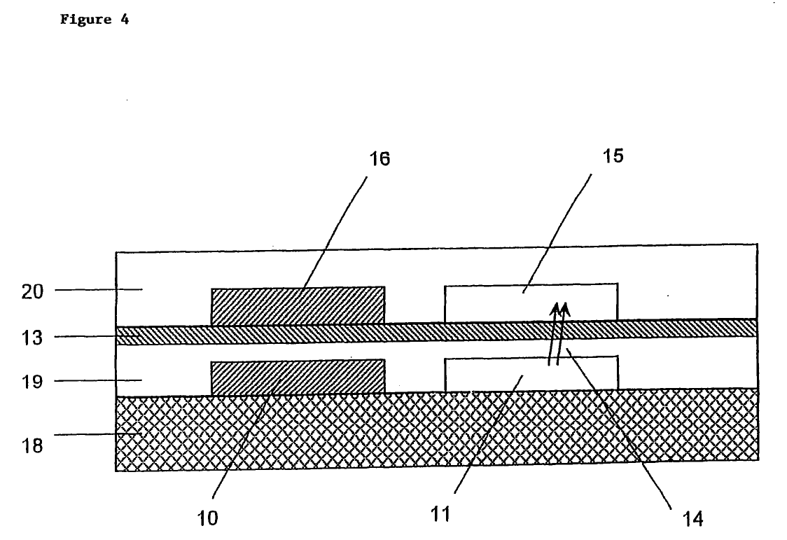

FIG. 4 shows a cross-section through an optical coupler.

In FIG. 1 the device shown is the pocket calculator 1 shown in an overall view from above. The following electronic organic components are combined in this device:

The organic display 2, which carries out the monitor function of the pocket calculator 1 and an organic energy storage unit 3, such as an organic solar cell unit and/or battery, which supplies the energy for the pocket calculator 1.

The pocket calculator 1 also has a keyboard 4, which operates for example by means of an organic electronics system 6, for example pressure sensors, which are housed below the respective keys and therefore cannot be seen. The components listed above are located here on a single substrate 5, which can for example be a flexible substrate such as a film.

A pocket calculator 1 is produced for example using large-scale processes, in which different organic components are applied to a substrate by printing, spraying, spin coating, etc. in a continuous method. In the simplest instance the substrates can be drawn over a number of rollers connected one behind the other, until the functional layers of the individual organic components are applied in their entirety. The coated substrates then only have to be cut, for an individual device such as a pocket calculator 1 to be manufactured.

The three components display 2, organic energy storage unit 3 and keyboard 4 have a functional connection, so that in operation the pocket calculator 1 displays the required results on the display 2 via activation of the keyboard 4 using the energy provided by the energy storage unit 3.

FIG. 2 shows the pocket calculator 1 in cross-section. At the bottom it shows the substrate 5, to which the organic display 2, the organic energy storage unit 3 and the keyboard 4 with the organic electronics system 6 below it are applied. All the components can be created by simply printing the substrate. This makes it possible to produce such devices at low cost and their use as disposable products is realistic.

FIG. 3 shows a circuit for an optical coupler. It shows the contacts or connections 8, 9, 12 and 17, the electronic driver unit 10, the light diode 11, a transparent, insulating separating layer 13, through which the light beam 14 penetrates, a receiver diode (light detector) 15, which is separated from the light diode 11 by the separating layer 13 and finally the electronic analysis unit 16.

FIG. 4 shows the same optical coupler in cross-section. On a substrate 18, which can also be a flexible substrate, are the light diode 11 with the electronic driver unit 10, on top of which there is a top layer 19 (optional), on which the insulating, transparent separating layer 13 is located, which in turn serves as it were as a substrate for the receiver diode 15 and the electronic analysis unit 16.

All components of the devices shown can for example be produced by simply printing, spraying and/or coating etc. with organic material.

Once the individual components have been produced on the substrate, it is recommended that the device be protected by an encapsulation unit 7, 20 from mechanical and/or other unwanted environmental influences.

The invention relates to a device with at least two electronic components, which comprise at least one organic functional layer and a method for producing the same. Unlike known devices, the device comprises at least two components made from organic material and is therefore significantly cheaper and less complicated to produce than the devices known to date, in which there is always a combination of organic and conventional electronic components. In certain circumstances conventional silicon semiconductor technology can be dispensed with completely here.

1. Device with at least two electronic organic components, with each of the two components comprising at least one organic functional layer and having a direct or indirect functional connection.

2. Device according to claim 1, in which the components are applied to a substrate.

3. Device according to one of claims 1 or 2, in which the substrate is a flexible substrate.

4. Device according to one of the preceding claims, in which the components are encapsulated.

5. Device according to one of the preceding claims, in which the functional connection is achieved by means of circuit board conductors with organic electronics systems.

6. Method for producing a device with at least two electronic organic components, with the electronic organic components being such that they can be produced by printing, spraying, coating, embossing and/or applying with a doctor blade, imprinting, heating and/or irradiating a substrate.

7. Method according to claim 6, in which production takes place in a continuous process.

8. Method according to one of claims 6 or 7, in which production is large-scale.
